(19) United States
(12) Patent Application Publication
(10) Pub. No.: US 2011/0117377 A1
(43) Pub. Date: May 19, 2011

(54) Coating process and corrosion protection coating for turbine components

(76) Inventors: Claus Krusch, Mulheim an der Ruhr (DE); Werner Stamm, Mulheim an der Ruhr (DE)

(21) Appl. No.: 13/003,055

(22) PCT Filed: Jun. 23, 2009
(86) PCT No.: PCT/EP2009/057803

§ 371 Date: Jan. 7, 2011

(30) Foreign Application Priority Data
Jul. 11, 2008 (EP) 08012574.3

(51) Int. Cl. C23C 16/34; H05H 1/24; B32B 15/04

(52) U.S. Cl. 428/457; 427/255.34; 427/569

(57) ABSTRACT

A process for coating a surface of a potentially fuel-conducting component of a turbine, in particular a gas turbine, in which the surface is firstly coated with a titanium nitride layer and subsequently with an a-aluminium oxide layer by means of chemical vapour deposition, is disclosed. In addition, a turbine component for example a component of a gas turbine, which includes a base material and a potentially fuel-conducting surface is described. The surface has an intermediate layer including titanium nitride and a covering layer including a-aluminium oxide.

### CROSS REFERENCE TO RELATED APPLICATIONS

This application is the US National Stage of International Application No. PCT/EP2009/057803, filed Jun. 23, 2009 and claims the benefit thereof. The International Application claims the benefits of European Patent Office application No. 08012574.3 EP filed Jul. 11, 2008. All of the applications are incorporated by reference herein in their entirety.

### FIELD OF INVENTION

The present invention relates to a process for coating a surface of a potentially fuel-conducting component of a turbine component. It also relates to a corrosion protection coating for a turbine component, for example a gas turbine component.

### BACKGROUND OF INVENTION

Fuel-conducting components of gas turbines based on the material 16Mo3 generally show signs of corrosion during operation. One possible cause is the formation of sulfuric acid, which is produced by the interaction of condensing atmospheric moisture with hydrogen sulfide (H₂S) present in the fuel. But at relatively high temperatures, in particular at over 60° C., hydrogen sulfide (H₂S) in the gaseous state can also lead to sulfidation. The base material 16Mo3 of the components concerned, particularly in the burner region, has no resistance to mineral acids or H₂S.

Corrosion can be observed in particular in the region of the interior spaces of a premix burner, through which gas or air flows, depending on the operating mode. Corrosion particles produced in the interior spaces by becoming detached from the inner walls can lead to blockages of the gas outlet nozzles. This results in unplanned or extended system outages caused by emergency trips, unbalanced loads, combustion oscillations and reduced power.

Previously, the burner components were in some instances produced from corrosion-resistant material. However, the use of such, typically nickel-based, alloys entails a series of disadvantages. Apart from the higher material costs, nickel-based alloys have inferior working or machining properties. The significantly lower thermal conductivity in comparison with 16Mo3 results in higher thermally induced stresses as a result of greater temperature gradients.

### SUMMARY OF INVENTION

It is therefore an object of the present invention to provide a process for the corrosion-reducing coating of a surface of a potentially fuel-conducting component of a gas turbine. It is a further object to provide an advantageous turbine component which comprises a base material and a potentially fuel-conducting surface. Moreover, it is an object of the present invention to provide an advantageous gas turbine.

The first object is achieved by a process for coating a surface of a potentially fuel-conducting component of a turbine component, in particular of a gas turbine, as claimed in the claims. The second object is achieved by a turbine component which comprises a base material and a potentially fuel-conducting surface as claimed in the claims. The third object is achieved by a gas turbine as claimed in the claims. The dependent claims comprise further, advantageous refinements of the present invention. The features are advantageous both individually and in combination with one another.

Within the scope of the process according to the invention for coating a surface of a potentially fuel-conducting component of a turbine component, the surface is coated firstly with a titanium nitride layer and subsequently with an α-aluminum oxide layer by means of chemical vapor deposition (CVD). Preferably, a surface which comprises steel of the grade 16Mo3 is coated. The corrosion protection layer produced by means of the process according to the invention combines the advantages of the material 16Mo3 with respect to thermal-mechanical behavior, material costs and machining properties with the corrosion resistance to sulfuric acid or sulfidation.

The corrosion protection principle according to the invention is based on the physical separation of corrosive medium, for example gas contaminated with sulfuric acid or H₂S, and a base material, for example steel of the grade 16Mo3. The layer structure is made up of two layers, that is to say it consists of an intermediate layer and a top layer. The component surface is coated firstly with a titanium nitride (TiN) intermediate layer and subsequently with an impermeable α-aluminum oxide (α-Al₂O₃) top layer by means of chemical vapor deposition (CVD). The titanium nitride (TiN) intermediate layer is required, since direct bonding of α-aluminum oxide on steel of the grade 16Mo3 could not be achieved in the course of laboratory tests.

Within the scope of the process according to the invention, the surface to be coated may first be heated. The heated surface may be coated with titanium nitride and directly thereafter with α-aluminum oxide. The surface coated in this way may then be cooled down again. In principle, the coating with titanium nitride and α-aluminum oxide may be carried out in the same furnace. The surface may in principle be coated with titanium nitride by gas phase ammonolysis (4 TiCl₄+6 NH₃→4 TiN+16 HCl+N₂+H₂) and/or hydrogen plasma coating (2 TiCl₄+4 H₂+N₂→2 TiN+8 HCl).

The surface to be coated can therefore be coated sequentially while passing through a CVD furnace. This requires a CVD furnace in which not only the α-Al₂O₃ deposition but also the deposition of TiN by gas phase ammonolysis (4 TiCl₄+6 NH₃→4 TiN+16 HCl+N₂+H₂), hydrogen plasma coating (2 TiCl₄+4 H₂+N₂→2 TiN+8 HCl) or other suitable methods can be carried out.

The surface to be coated may be heated in the course of the chemical vapor deposition with a temperature increase of between 700° C./h and 900° C./h, preferably with a temperature increase of 800° C./h. Furthermore, the surface may be heated and/or cooled in the course of the chemical vapor deposition under a pressure of between 50 mbar and 150 mbar, preferably under a pressure of 100 mbar.

Moreover, during the heating and/or cooling in the course of the chemical vapor deposition, the surface may be flushed with a gas comprising argon and hydrogen. For example, during the heating it may be flushed with a gas comprising 80% to 85%, preferably 83%, argon and 15% to 20%, preferably 17%, hydrogen. During the cooling, it may, for example, be flushed with a gas comprising 15% to 20%, preferably 17%, argon and 80% to 85%, preferably 83%, hydrogen. Flushing is advantageously carried out with a gas flow of 16 to 20 liters per hour, preferably with 18 liters per hour. However, these figures are dependent on the size of the furnace that is used.

The surface to be coated may be cooled in the course of the chemical vapor deposition with a temperature decrease of between 300° C./h and 500° C./h, advantageously with a temperature decrease of 400° C./h.

The surface may, furthermore, be coated in the course of the chemical vapor deposition at a temperature of between 900° C. and 1100° C., alternatively at a temperature of between 1000° C. and 1100° C., preferably at a temperature of 1050° C. The surface may be coated with a gas flow of 16 to 20 liters per hour, preferably with 18 liters per hour. The surface may, for example, be coated with titanium nitride under a pressure of between 20 mbar and 40 mbar, preferably under a pressure of 30 mbar. It may, furthermore, be coated with α-aluminum oxide under a pressure of between 80 mbar and 120 mbar, preferably under a pressure of 100 mbar.

In the event that the surface is coated with titanium nitride in the course of the chemical vapor deposition under a pressure of 20 mbar to 40 mbar, the pressure may be made up of 0.2 mbar to 1 mbar TiCl₄, 18.4 mbar to 28 mbar H₂ and 2.4 mbar to 11 mbar N₂. If the surface is coated with titanium nitride under a pressure of 30 mbar, this pressure may, for example, be made up of 0.4 mbar TiCl₄, 23.68 mbar H₂ and 5.92 mbar N₂.

In the event that the surface is coated with α-aluminum oxide in the course of the chemical vapor deposition under a pressure of 80 mbar to 120 mbar, the pressure may comprise 20 mbar to 25 mbar Ar, 10 mbar to 15 mbar CO₂, 20 mbar to 40 mbar H₂ and 2 mbar to 6 mbar HCl. In this case, 20 mbar to 40 mbar H₂ and 2 mbar to 6 mbar HCl may be fed to an AlCl₃ generator. If, for example, the surface is coated with α-aluminum oxide under a pressure of 100 mbar, this pressure may comprise 22.7 mbar Ar, 12 mbar CO₂, 30 mbar H₂ and 4 mbar HCl. In this case, 30 mbar H₂ and 3.9 mbar HCl may be fed to an AlCl₃ generator.

Furthermore, in the course of the chemical vapor deposition, the surface may be coated with titanium nitride during a time period of between two hours and four hours, preferably during a time period of three hours. Moreover, it may be coated with α-aluminum oxide during a time period of between three hours and five hours, preferably during a time period of four hours.

The process according to the invention has the advantage that it can be used for any desired geometries and is also suitable in particular for inner coating. Moreover, it opens up the possibility of coating narrow internal channels, since a gaseous carrier medium is used. Moreover, in comparison with a nickel-based alloy, significantly lower material and working or machining costs of 16Mo3 are incurred. With the aid of the process according to the invention, lower coating costs overall are incurred.

A further advantage of the process according to the invention is that the coating produced has a more favorable thermal-mechanical behavior in comparison with nickel-based alloys. In particular, as a result of the lower temperature gradient, lower thermally induced stresses occur. It has been possible in laboratory testing to demonstrate corrosion resistance to gas contaminated with sulfuric acid or H₂S and thermal shock resistance of the coating produced by the process according to the invention.

The turbine component according to the invention comprises a base material and a potentially fuel-conducting surface. The surface has an intermediate layer comprising titanium nitride and a top layer comprising α-aluminum oxide. That is to say that the surface is coated with titanium nitride and the titanium nitride coating is in turn coated with α-aluminum oxide. The turbine component according to the invention may be in particular a component of a gas turbine. For example, the turbine component according to the invention may be a component of a burner.

The turbine component according to the invention has the advantage that the coating is corrosion-resistant to sulfuric acid and is resistant to thermal shocks. The α-aluminum oxide layer provides the corrosion resistance and the titanium nitride layer provides the bonding of the α-aluminum oxide layer to the base material.

The base material may be, in particular, steel of the grade 16Mo3. The turbine component according to the invention is in this case distinguished by significantly lower material and working or machining costs of 16Mo3 in comparison with nickel-based alloys. Moreover, as a result of the lower temperature gradient, and consequently the lower thermally induced stresses, the thermal-mechanical behavior is more favorable in comparison with nickel-based alloys.

The gas turbine according to the invention comprises a turbine component according to the invention, as described above. The gas turbine according to the invention has the same advantages as the turbine component according to the invention.

### BRIEF DESCRIPTION OF THE DRAWINGS

Further features, properties and advantages of the present invention are described in more detail below on the basis of an exemplary embodiment with reference to the accompanying figures. The configurational variants are advantageous both individually and in combination with one another.

FIG. 1 schematically shows the principle of a CVD coating furnace for the deposition of α-Al₂O₃ and TiN.

FIG. 2 schematically shows a section through the component coating according to the invention.

FIG. 3 schematically shows a gas turbine.

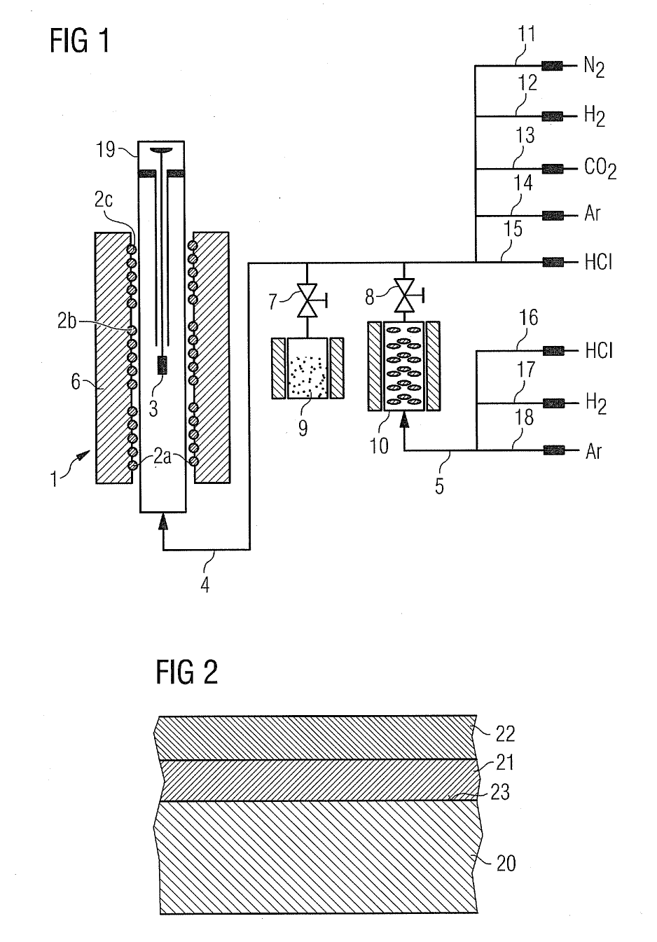

An exemplary embodiment of the present invention is described in more detail below on the basis of FIGS. 1 to 3.

### DETAILED DESCRIPTION OF INVENTION

FIG. 1 schematically shows a CVD furnace 1 for coating a gas turbine component 3, which consists for example of steel of the grade 16Mo3, by means of chemical vapor deposition (CVD). The CVD furnace 1 comprises a housing 6. Arranged inside the housing 6 is an interior space 19, in which the component 3 to be coated can be placed. Arranged on the side of the housing 6 that is facing the interior space 19 are heating coils 2. In the present exemplary embodiment, three heating coils 2a, 2b and 2c are arranged, whereby three heating zones can be realized.

The CVD furnace 1 shown in FIG. 1 is suitable both for coating with titanium nitride and for coating with α-aluminum oxide. The two coating steps can be carried out sequentially while passing through a furnace, that is to say without cooling and re-heating of the component between the coating with titanium nitride and α-aluminum oxide. The gaseous starting compounds required for the chemical vapor deposition are conducted into the interior space 19 of the CVD furnace 1 via a gas line 4. The interior space 19 may, for example, have a diameter of 44 mm.

Connected to the gas line 4 via a valve 7 is a TiCl₄ evaporator 9. In addition, an AlCl₃ generator with aluminum pellets is connected to the gas line 4 via a further valve 8. In addition, nitrogen, hydrogen, carbon dioxide, argon and hydrogen chloride can be introduced into the gas line 4 respectively via a nitrogen feed line 11, a hydrogen feed line 12, a carbon dioxide feed line 13, an argon feed line 14 and a hydrogen chloride feed line 15.

Furthermore, the AlCl₃ generator 10 is connected via a gas line 5 to a hydrogen chloride feed line 16, a hydrogen feed line 17 and an argon feed line 18. Through these feed lines 16, 17 and 18, hydrogen chloride, hydrogen and argon can be introduced into the AlCl₃ generator via the gas line 5.

In the CVD furnace shown in FIG. 1, not only the α-Al₂O₃ deposition but also the deposition of TiN by gas phase ammonolysis (4 TiCl₄+6 NH₃→4 TiN+16 HCl+N₂+H₂), hydrogen plasma coating (2 TiCl₄+4 H₂+N₂→2 TiN+8 HCl) or other suitable processes can be carried out.

For coating a component 3 with a titanium nitride (TiN) intermediate layer, the component 3 is firstly heated at a heating rate of 800° C./h under a pressure of 100 mbar. During this, the component 3 is flushed with a gas, which comprises 83% argon and 17% hydrogen. The gas flow is in this case, for example, 18 liters per hour, depending on the size of the furnace. In this case, the argon is introduced via the argon feed line 14 and the hydrogen is introduced via the hydrogen feed line 12 into the gas line 4 and via the latter into the interior space 19 of the CVD furnace 1.

The subsequent titanium nitride deposition is performed at a temperature of 1050° C. and under a pressure of 30 mbar. In this case, the component 3 is flushed with a precursor gas comprising TiCl₄, H₂ and N₂, with a gas flow of, for example, 18 liters per hour. The titanium chloride (TiCl₄) is in this case introduced from the TiCl₄ evaporator 9 via the valve 7 into the gas line 4 and passes from there into the interior space 19 of the CVD furnace 1. Moreover, the hydrogen (H₂) is introduced via the hydrogen feed line 12 and the nitrogen (N₂) is introduced via the nitrogen feed line 11 into the gas line 4. The precursor gas is in this case made up such that the TiCl₄ contributes 0.40 mbar, the H₂ contributes 23.68 mbar and the N₂ contributes 5.92 mbar to the total pressure of 30 mbar. The deposition is performed during a time of three hours.

In the course of the titanium nitride deposition, the temperature should not be kept at 1050° C. for long to avoid phase transitions. The temperature may, in particular, also be kept at 950° C.

Following the titanium nitride deposition, the component 3 is cooled at a rate of 400° C./h under a pressure of 100 mbar. In this case, the component 3 is flushed with a gas comprising 17% argon and 83% hydrogen at a gas flow of 18 liters per hour. The argon is in turn introduced via the argon feed line 14 and the hydrogen is introduced via the hydrogen feed line 12 into the gas line 4 and via the latter into the interior space 19 of the CVD furnace 1.

For producing the α-Al₂O₃ top layer, the component 3 is in turn heated at a heating rate of 800° C./h under a pressure of 100 mbar and a gas flow of 18 liters per hour. The gas with which the component 3 is flushed during the heating is made up of 83% argon and 17% hydrogen and is conducted to the component 3 via the feed lines 4, 12 and 14.

During the subsequent α-aluminum oxide deposition, the component 3 is flushed with a gas comprising argon, carbon dioxide, hydrogen and hydrogen chloride at a temperature of 1050° C. The gas flow is in this case, for example, 18 liters per hour and the pressure is 100 mbar. The deposition is performed during a time of four hours. During the deposition, hydrogen under a pressure of 30 mbar is fed to the AlCl₃ generator 10 via the gas line 5 and the hydrogen feed line 17. Furthermore, hydrogen chloride under a pressure of 3.9 mbar is fed to the AlCl₃ generator 10 via the gas line 5 and the hydrogen chloride feed line 16. The aluminum chloride produced with the aid of the AlCl₃ generator is introduced into the interior space 19 of the CVD furnace 1 via the valve 8 and the gas line 4. In addition, argon under a pressure of 22.7 mbar is introduced into the interior space 19 via the argon feed line 14 and via the gas line 4. In addition, carbon dioxide under a pressure of 12 mbar is introduced via the carbon dioxide feed line 13 and hydrogen under a pressure of 30 mbar is introduced via the hydrogen feed line 12 into the gas line 4 and via the latter into the interior space 19. In addition, hydrogen chloride under a pressure of 4 mbar is introduced via the hydrogen chloride feed line 15 into the gas line 4 and via the latter into the interior space 19.

After completion of the deposition process, the component 3 is cooled at a cooling rate of 400° C./h. In this case, the component 3 is flushed with a gas comprising 12% argon and 83% hydrogen at 100 mbar. The gas flow is in this case, for example, 18 liters per hour. Argon and hydrogen are conducted to the component 3 via the feed lines 4, 12 and 14.

In principle, the titanium nitride deposition and the α-aluminum oxide deposition may be performed one directly after the other, that is to say while passing through a furnace. In this case, the component 3 does not have to be cooled down and heated up again between these two deposition processes.

The coating achieved with the aid of the process according to the invention is schematically represented in FIG. 2. FIG. 2 shows a section through a part of a potentially fuel-conducting component of a gas turbine 20 as an example of a component 3 coated according to the invention. The component 20 is coated with a titanium nitride intermediate layer 21 and with an α-aluminum oxide top layer 22. The potentially fuel-conducting component 20 may, for example, consist of steel of the grade 16Mo3. The component 20 may, in particular, be a burner component.

The surface 23 of the potentially fuel-conducting component 20 is effectively protected against corrosion effects by the coating with titanium nitride 21 and α-aluminum oxide 22. In addition, there is very good thermal shock resistance of the coated surface. Thermal shock tests in which the coated component 3, 20 heated to 420° C. was quenched with water at 20° C. show that the component does not have any cracks or damage even after repeating the heating and quenching of the component one hundred times. No changes in the composition of the component or the coating could be observed either.

In principle, the component 3 according to the invention and the potentially fuel-conducting component 20 may be a component of a gas turbine.

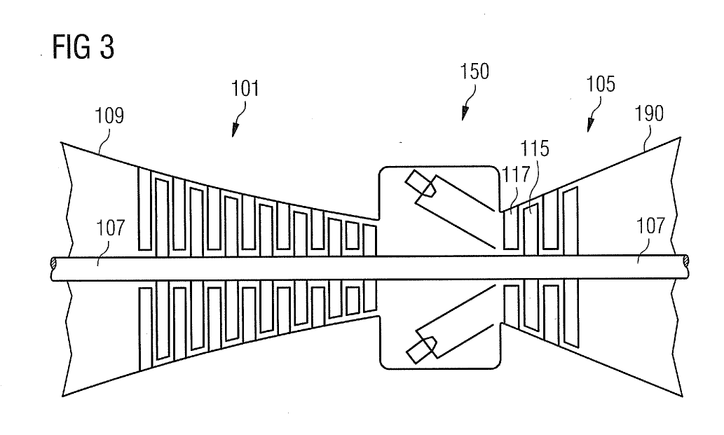

FIG. 3 schematically shows a gas turbine. A gas turbine has in the interior a rotor with a shaft 107, which is rotatably mounted about an axis of rotation and is also referred to as a turbine runner. Following one another along the rotor are an intake housing 109, a compressor 101, a burner arrangement 150, a turbine 105 and the exhaust housing 190.

The burner arrangement 150 communicates with a hot gas duct, for example of an annular faun. There, the turbine 105 is formed by a number of successive turbine stages. Each turbine stage is formed by blade rings. As seen in the direction of flow of a working medium, a row of stationary blades 117 is followed in the hot gas duct by a row formed by moving blades 115. The stationary blades 117 are in this case fastened to an inner housing of a stator, whereas the moving blades 115 of a row are attached to the rotor, for example by means of a turbine disk. Coupled to the rotor is a generator or a machine.

During the operation of the gas turbine, air is sucked in by the compressor 101 through the intake housing 109 and compressed. The compressed air provided at the end of the compressor 101 on the turbine side is passed to the burner arrangements 150 and mixed there with a fuel. The mixture is then burned in the combustion chamber to form the working medium. From there, the working medium flows along the hot gas duct past the stationary blades 117 and the moving blades 115. At the moving blades 115, the working medium expands, transferring momentum, so that the moving blades 115 drive the rotor and the latter drives the machine coupled to it.

1.-15. (canceled)

16. A process for coating a surface of a potentially fuel-conducting component of a turbine component, comprising:
coating the surface firstly with a titanium nitride layer; and
coating subsequently the surface with an α-aluminum oxide layer using chemical vapor deposition.

17. The process as claimed in claim 16, wherein the surface which comprises steel of the grade 16Mo3 is coated.

18. The process as claimed in claim 16, wherein the surface to be coated is first heated, the heated surface is coated with titanium nitride and directly thereafter coated with α-aluminum oxide, and the coated surface is then cooled down again.

19. The process as claimed in claim 16, wherein the coating with titanium nitride and α-aluminum oxide is carried out in the same furnace.

20. The process as claimed in claim 16, wherein the surface is coated with titanium nitride by gas phase ammonolysis or hydrogen plasma coating.

21. The process as claimed in claim 16, wherein the surface is heated during the chemical vapor deposition with a temperature increase of between 700° C./h and 900° C./h.

22. The process as claimed in claim 16, wherein the surface is heated and/or cooled during the chemical vapor deposition under a pressure of between 50 mbar and 150 mbar.

23. The process as claimed in claim 16, wherein, during the heating and/or cooling during the chemical vapor deposition, the surface is flushed with a gas comprising argon and hydrogen.

24. The process as claimed in claim 23, wherein during the heating the surface is flushed with the gas comprising 80%-85% argon and 15%-20% hydrogen.

25. The process as claimed in claim 23, wherein during the cooling the surface is flushed with the gas comprising 15%-20% argon and 80%-85% hydrogen.

26. The process as claimed in claim 16, wherein the surface is cooled during the chemical vapor deposition with a temperature decrease of between 300° C./h and 500° C./h.

27. The process as claimed in claim 16, wherein the surface is coated during the chemical vapor deposition at a temperature of between 900° C. and 1100° C.

28. The process as claimed in claim 16, wherein the surface is coated during the chemical vapor deposition with a gas flow of 16 l/h to 20 l/h.

29. The process as claimed in claim 16, wherein, during the chemical vapor deposition, the surface is coated with titanium nitride under a first pressure of between 20 mbar and 40 mbar and/or is coated with α-aluminum oxide under a second pressure of between 80 mbar and 120 mbar.

30. The process as claimed in claim 16, wherein, during the chemical vapor deposition, the surface is coated with titanium nitride during a first time period of between 2 h and 4 h and/or is coated with α-aluminum oxide during a second time period of between 3 h and 5 h.

31. A turbine component, comprising:
a base material; and
a potentially fuel-conducting surface,
wherein the surface includes an intermediate layer comprising titanium nitride and a top layer comprising α-aluminum oxide.

32. A gas turbine, comprising:
a turbine component, comprising:
a base material, and
a potentially fuel-conducting surface,
wherein the surface includes an intermediate layer comprising titanium nitride and a top layer comprising α-aluminum oxide.
